(19) United States
(12) Patent Application Publication
(10) Pub. No.: US 2024/0407075 A1
(43) Pub. Date: Dec. 5, 2024

(54) INVERTED PLASMA SOURCE

(71) Applicant: MKS INSTRUMENTS, INC., Andover, MA (US)

(72) Inventors: Gordon HILL, Andover, MA (US); Ron COLLINS, Andover, MA (US)

(73) Assignee: MKS INSTRUMENTS, INC., Andover, MA (US)

(21) Appl. No.: 18/631,119

(22) Filed: Apr. 10, 2024

Related U.S. Application Data
(60) Provisional application No. 63/495,193, filed on Apr. 10, 2023.

(51) Int. Cl. H05H 1/46

(52) U.S. Cl. CPC H05H 1/4652; H05H 2242/10

(57) ABSTRACT

A plasma source, comprising a plasma source body, comprising: a plurality of magnetic cores, a plurality of primary windings capable of being energized, and a cooling structure, wherein one or more sections of the plasma source body comprising a dielectric material, and wherein, when the plurality of primary windings are energized, a plasma forms around an outer portion of the plasma source body.

### REFERENCE TO RELATED APPLICATIONS

The present application claims priority to U.S. Prov. Pat. Appl. Ser. No. 63/495,193, entitled “Point of Use Inverted Toroidal Plasma Source,” filed on Apr. 10, 2023, the contents of which are incorporated by reference in its entirety herein.

### BACKGROUND

The cleaning of process byproducts in semiconductor processing is performed by reactive radical gas species that are generated by a plasma source. With remote plasma sources, this presents a significant challenge since the free radicals emitted by the source are prone to recombine before reaching the desired location of cleaning.

An inductively coupled plasma source can reach high power densities, and therefore generate more reactive gas radicals. Toroidal inductively coupled plasma sources (ICPs) are very efficient, in that a large fraction of the power in the primary winding is coupled into the plasma. However, toroidal ICPs can be difficult to ignite. Also, most toroidal plasma sources are enclosed in a plasma block with a gas inlet and outlet. Both the walls of the plasma block and the transport tube between the exit of the plasma source and the chamber leads to recombination losses of the reactive radicals that had been formed in the plasma.

Recombination losses increase with higher pressure. Typically, remote plasma sources require a transport tube to introduce the reactive radicals to the wafer processing chamber, and often the radicals must transport through an outlet or showerhead. As higher flux of reactive radicals is desired, the input flow rate through the remote plasma source increases, which drives the need for higher power and cooling. However, as the flow rate increases, the pressure in the plasma source and transport tubes will increase, which further increases undesirable recombination. Due to these factors, increasing flow rate and power leads to diminishing returns in increasing the quantity of reactive radicals delivered to the wafer processing chamber.

Furthermore, as the size of the conventional toroidal plasma source increases, the required loop voltage increases. The need to operate at higher pressure also increases the loop voltage. Higher loop voltage also increases the heating of the cores.

Various plasma sources configured to provide a toroidal plasma are known in the art. While these various systems have proven somewhat useful, a number of shortcomings have been identified. For example, prior art systems are used for wafer processing, not targeted cleaning. As such, the prior art plasma sources tend to be large and require substantial power to ignite and maintain a plasma. Further, the prior art plasma sources art systems result in undesirable radical recombination, thereby limiting their cleaning efficiency. In light of the foregoing, there is an ongoing need for a plasma source which may be positioned proximate to a cleaning target area, thereby minimizing radical recombination. In addition, there is an ongoing need for a plasma source which may require lower power to ignite and maintain a plasma within a plasma chamber.

### SUMMARY

The present application discloses various embodiments of plasma sources configured to overcome the above listed problems in the art and to provide point of views plasma sources that find applicability in lower chamber cleaning, foreline line cleaning, oxygen cleaning applications and point of use cleaning.

In one embodiment, present application discloses a plasma source comprising a plasma source body, the plasma source body comprising: a plurality of magnetic cores, a plurality of primary windings capable of being energized, and a cooling structure, wherein one or more sections of the plasma source body comprises a dielectric material, and wherein, when the plurality of primary windings are energized, a plasma forms around an outer portion of the plasma source body.

In accordance with an embodiment of the present invention the plasma source proposed further comprises potting situated on the inner portion of the plasma source body. In accordance with a further embodiment of the present invention the plasma source body comprises an electrode capable of forming a dielectric barrier discharge for ignition.

The plasma source body comprised by the plasma source of a present invention may have either a torus shape or a cylindrical shape.

The cooling structure comprises water passages, such as a plurality of pipes capable of conducting heat after a temperature threshold of the plurality of pipes has been exceeded. The plasma source comprises a torus shaped plasma source body having a diameter of less than 1 inch to approximately 4 inches, and a height of about 1.5 inches, and capable of operating at about 500-2000 W. Exemplarily, the plasma source has a diameter of about 3.25 inches. A ferrite core is coupled with a portion of the cooling structure, and the plasma source body is coupled with a second portion of the cooling structure.

For the embodiment of the present invention in which the plasma source comprises a vessel of a toroidal shape, the torus shaped plasma source body has a diameter of less than 1 inch to approximately 4 inches, and a height of about 1.5 inches, and is capable of operating at about 500-2000 W.

In accordance with a further embodiment of the present invention, the plasma source has a diameter of about 3.25 inches, the plurality of magnetic cores are ferrite cores, and the plurality of magnetic cores is encased in a thermally conductive potting. The input gas is injected into a plasma discharge region.

In a further yet embodiment, the present invention comprises a plasma source, comprising a plasma source body formed from at least one plasma source body member and at least one dielectric break, the plasma source body defining at least one plasma source body passage therein, at least one ferrite core positioned within the plasma source body passage, at least one primary winding traversing at least a portion of the plasma source body, the primary winding positioned proximate to the ferrite core, the primary winding in communication with at least one source RF energy, wherein the application of RF energy to the primary winding results in the formation of a plasma proximate to an outer surface of the plasma source body, and at least one thermal management structure positioned within the plasma source body passage proximate to the ferrite core, the thermal management structure in fluid communication with at least one fluid source via at least one thermal management system inlet on the plasma source body.

The plasma source of the present invention has plasma source body further comprising at least one electrode positioned within the plasma source body, the electrode capable of forming a dielectric barrier discharge for ignition of the plasma. The plasma source body has either a torus shape or a cylindrical shape. The plasma source comprises a torus shaped plasma source body having a diameter of less than 1 inch to approximately 4 inches, and a height of about 1.5 inches, and capable of operating at about 500-2000 W. The at least one ferrite core is encased in a thermally conductive potting.

### BRIEF DESCRIPTION

The above and other aspects, features and advantages of the inverted plasma source disclosed herein will become more apparent from the subsequent description thereof, presented in conjunction with the following drawings, wherein:

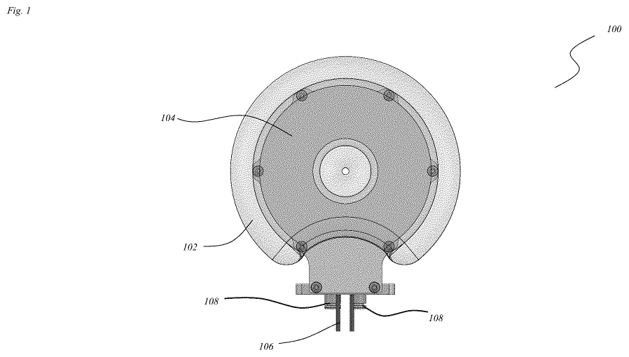

FIG. 1 is a top view of a toroidal plasma source in accordance with an embodiment of the inverted plasma source;

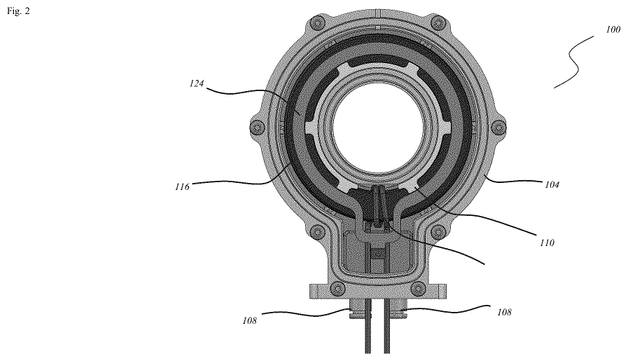

FIG. 2 is a through section of the top view of a plasma source in accordance with an embodiment of the inverted plasma source;

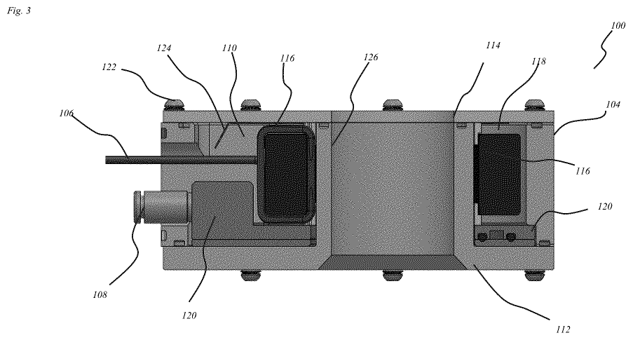

FIG. 3 is a cross section of a lateral view of a plasma source in accordance with an embodiment of the inverted plasma source;

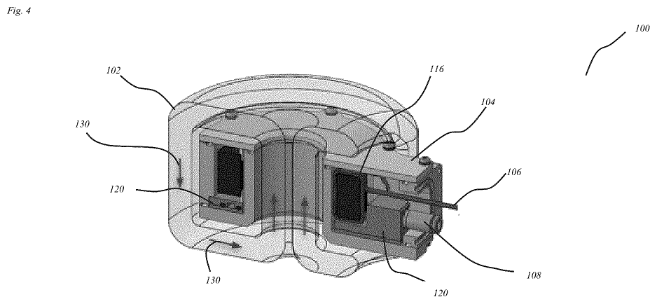

FIG. 4 is another cross-section illustration of the plasma source in accordance with an embodiment of the inverted plasma source;

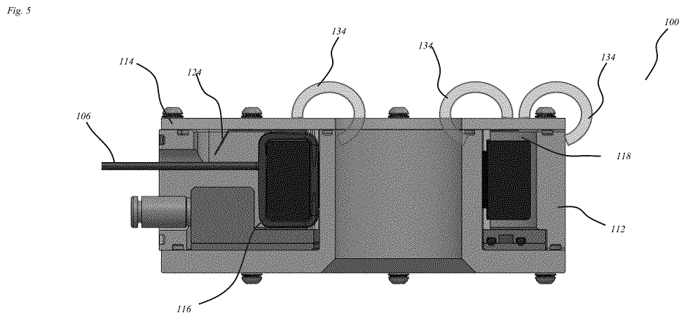

FIG. 5 is as well a representation of the plasma source in accordance with an embodiment of the inverted plasma source in a cross section lateral view;

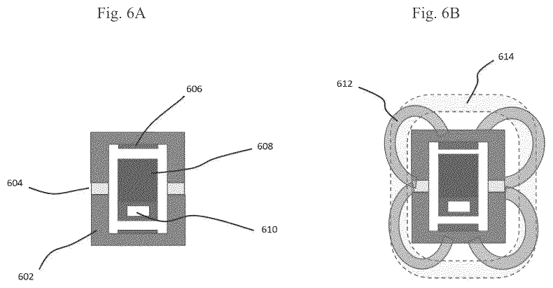

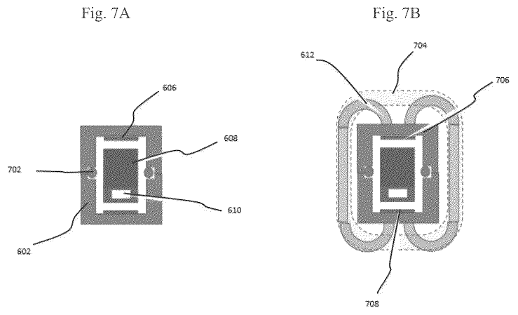

FIGS. 6 and 7 are further views of the exemplary plasma source in cross-section, in a side view;

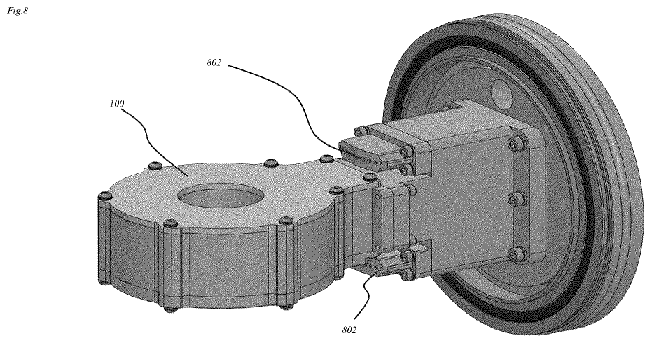

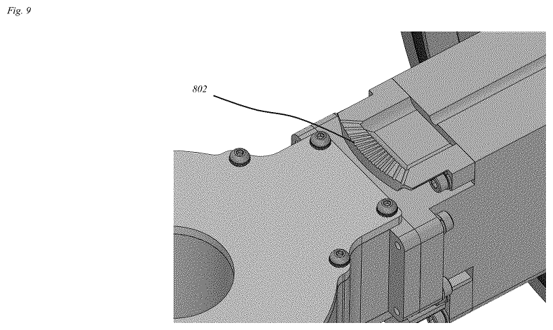

FIGS. 8 and 9 are top views of a toroidal plasma source in accordance with an embodiment of the inverted plasma source with a plurality of gas inlets;

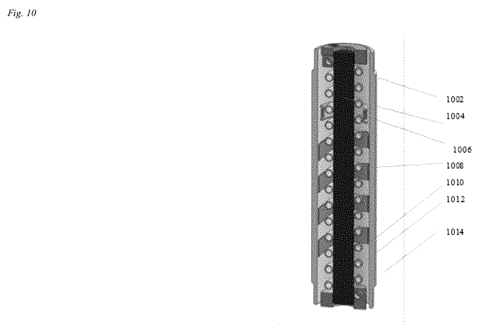

FIG. 10 is a side view in cross section of an inverted rod implementation plasma, source in accordance with an alternative embodiment of the inverted plasma source;

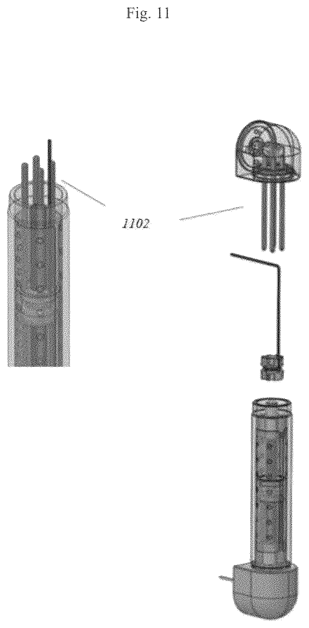

FIG. 11 illustrates a rod plasma source with heat pipes, in accordance with an embodiment of the inverted plasma source;

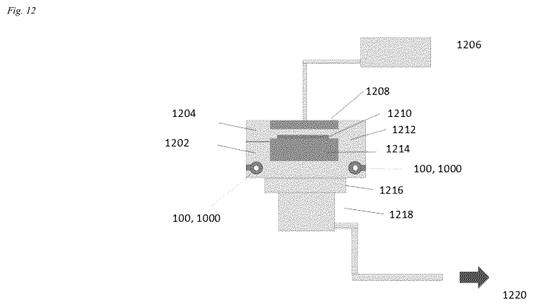

FIG. 12 illustrates an environment in which the plasma sources of the inverted plasma sources may be included;

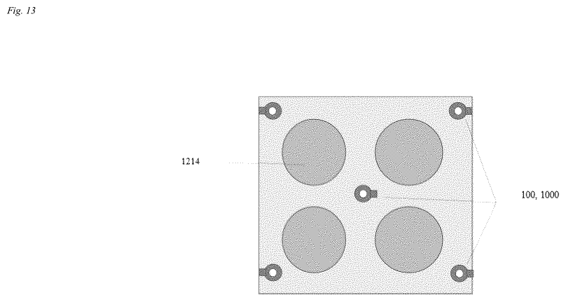

FIG. 13 illustrates the placement of multiple plasma sources in accordance with the inverted plasma source in a chamber;

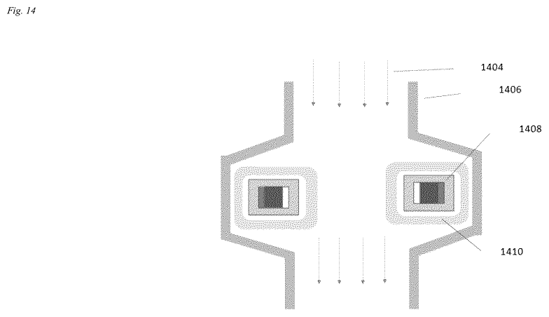

FIG. 14 illustrates an implementation of the toroidal plasma source in accordance with the inverted plasma source in pipes;

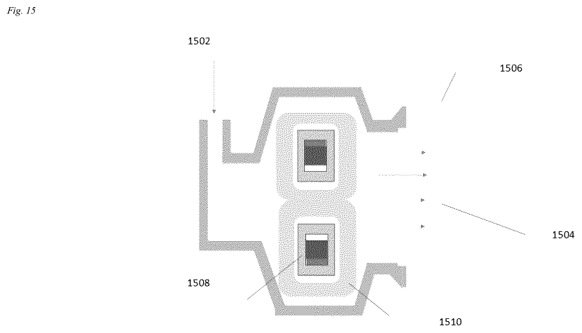

FIG. 15 shows an alternate implementation enclosing a plasma source in a compact vacuum enclosure; and

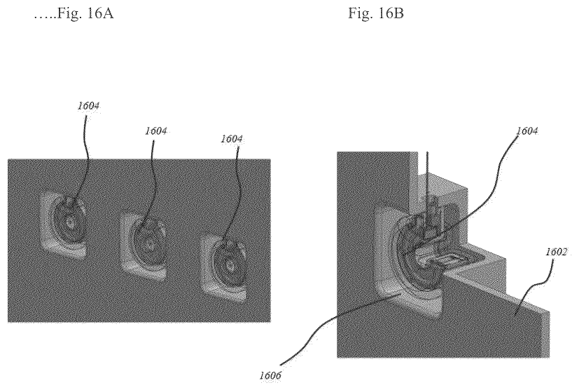

FIG. 16 shows an implementation of multiple point of use plasma sources installed in alcoves formed in the side wall of a vacuum chamber.

### DETAILED DESCRIPTION

The present application discloses various embodiments of an inverted plasma source. The proposed plasma source exhibits an inverted geometry, compared to conventional, for example toroidal, remote plasma source implementations. While exemplary non-inverted sources are conventional toroidal remote plasma sources (RPSs), where the vacuum is contained on the inside of a vacuum vessel, and the ferrite core, cooling, and primary winding are on the outside of the vacuum vessel, by a plasma with “inverted” geometry is understood a plasma source wherein vacuum is established on the outside of the of a plasma source body or vessel of the plasma source and the magnetic/ferrite core, cooling structure and, and primary winding are on the inside of the vessel. Optionally, the vessel may have either a toroidal geometry or a cylindrical geometry. Throughout the document the terms “plasma source body” and “vessel” are used interchangeable and are ascribed the same meaning.

FIGS. 1-3 show various views of an embodiment of a plasma source. The plasma source 100 illustrated in FIG. 1 is a toroidal plasma source, which exhibits an inverted geometry, although those skilled in the art will appreciate that the plasma source may have any desired shape. As it will be described in detail in the following portions of this document, the plasma source 100 includes at least one plasma source body or vessel 104 configured to generate at least one plasma 102. At least one primary winding 106 may be used to provide energy to at least one component within the plasma source body 104. Further, in the illustrated embodiment, the plasma source 100 may include at least one thermal management inlet/outlet 108 (hereinafter inlet) configured to permit active thermal management of the plasma source 100 during use. As such, the thermal management inlet may be in fluid communication with at least one fluid source (not shown).

When a vacuum is established on the outside of the plasma source body 104, the primary winding 106 may be energized with RF energy. At least one generated plasma 102 forms on the exterior of the plasma source 100, forming poloidal current loops around the minor diameter of the torus, on the outside of the vessel or plasma source body 104. Hereinafter vessel and plasma source body 104 may be used interchangeably. The current loops may overlap in the center of the torus.

The plasma source 100 may be manufactured in any variety of sizes, shapes, and transverse dimensions. In one embodiment, the plasma source 100 may be quite small. For example, in one specific embodiment the plasma source 100 has a diameter of about 3.25 inches and a height of 1.5 inches, although those skilled in the art will appreciate that the plasma source 100, and various components thereof may be manufactured in desired transverse dimension or size within this range. Further, the plasma source 100 may be configured to operate at any desired power. For example, in one embodiment the plasma source 100 operates at about 500-2000 W, although those skilled in the art will appreciate lower or higher powers may be used with the present embodiment of the plasma source 100. In one embodiment, the plasma source 100 may be installed in a wafer manufacturing lower chamber region, below a wafer pedestal and above a pressure control valve or chamber bottom. Alternatively, the plasma source 100 may be installed in the exhaust pumping lines, above a deposition trap, or upstream of the chamber. As such, at least one plasma source 100 may be used in any variety of locations within a semiconductor wafer manufacturing or processing systems. The size of the plasma source can be scaled to a range of sizes, from an inside diameter of less than about 1 inch, to approximately about 4 inches or more.

Referring to FIGS. 2 and 3, in one embodiment the plasma source 100 may include a one-piece toroidal ferrite or magnetic core 116 located within the plasma source body 104. In alternate constructions, the plasma source 100 uses multiple magnetic core sections, for example pressed together with springs, to form larger sizes that are non-circular in shape (e.g. square, rectangular, or polygon shaped). An alternate embodiment may include multiple ferrite cores 116. One common primary winding 106 can form around multiple cores 116 that are stacked. Alternatively, each core can have its own primary winding 106. Multiple primary windings 106 can be wired in series or in parallel. At higher pressures (1-10 Torr) the plasma 102 tends to form more tightly to the exterior surfaces of the plasma source 100. At lower pressure (1 mTorr-1 Torr) the plasma used tends to grow and extend beyond the torus. The size of the discharge will also depend on the gas type. With NF3 or an electronegative gas, the plasma 102 is smaller and will form tightly to the plasma source structure. With a gas such as Argon, Oxygen, or Nitrogen, the plasma 102 expands beyond the plasma source 100. A larger plasma 102 can be advantageous to cleaning with gas, such as oxygen or hydrogen, which rapidly recombines. As evident from FIG. 1, the plasma source 100 comprises a plasma source body 104 in form of a torus, comprising at least a plurality of primary windings 106 capable of being energized. Exemplarily, the torus shaped plasma source body 104 may have a diameter of less than 1 inch to approximately 4 inches, and a height of about 1.5 inches, and is capable of operating at about 500-2000 W, while the plasma source 100 has a diameter of about 3.25 inches.

As shown in FIGS. 2 and 3, the plasma source 100 comprises a plasma source body 104 formed from a plasma source body member 112 and at least one the dielectric break body member 114. In one embodiment, the plasma source body member 112 comprises an aluminum body although those skilled in the art will appreciate that any variety of materials may be used to form the plasma source body 104. The dielectric break body member 114 may be manufactured from alumina or one or more materials having similar electrical properties to alumina. In the illustrated embodiment, the upper surface of the plasma source body 104 comprises the dielectric break body member 114. Those skilled in the art will appreciate that any surface of the plasma source body 104 may comprises the dielectric break body member 114. For example, the body member structure 126 may be formed from alumina and, as such, may form the dielectric break body member 114. At least one plasma body source passage 110 is formed within the plasma source body 104 by the plasma source body member 112 and the dielectric break body member 114. One or more fasteners 122 may be used to couple the dielectric break body member 114 to the plasma source body member 112.

Referring again to FIGS. 2 and 3, at least one ignition electrode 124 may be positioned within the plasma source body passage 110. Hereafter, the terms ignition electrode and starter electrode are used interchangeably and refer to a dielectric barrier discharge (or DBD), which is considered a subset of a capacitively coupled plasma source. During use, the electrode 124 can ignite a plasma very reliably, and therefore is a good temporary ignition source for transitioning to the higher powered inductively coupled plasma. As shown, the electrode 124 may be positioned proximate to the ferrite core 116 located within the plasma source body passage 110. As shown in FIG. 2, at least a portion of the primary winding 106 is positioned proximate to at least one ferrite and/or magnetic core 116. In the illustrated embodiment, the primary winding 106 is wrapped around at portion of the ferrite core 116, although other configurations are considered. During use, the primary winding 106 is configured to provide energy (e.g. RF energy) and create at least one electric field proximate to the ferrite core 116. At least one thermal epoxy/potting cavity 118 may encase the toroidal ferrite core 116. In the illustrated embodiment the potting cavity 118 is located proximate to the dielectric break body member 114. The plasma source 100 illustrated in FIGS. 1-3 may include at least one integrated thermal management structure or cooling structure 120. The thermal management structure 120 is in communication with at least one thermal management inlet/outlets 108 formed in the plasma source body 104. During use, one or more fluids may be flowed through the thermal management system 120 via the inlet/outlet 108 thereby permitting the temperature of the plasma source body 104 and various components thereof to be selectively controlled. In one embodiment, the thermal management structure 120 may comprise a closed structure that forms an enclosed channel for containing at least one fluid. The closed structure of the thermal management structure 120 may be formed by brazing, bonding or sealing machined parts. Alternatively, the cooling structure could also be comprised of a simple bent tube. Optionally, the thermal management structure 120 may be manufactured from any variety of materials, including copper, stainless steel, or other materials.

As shown in FIG. 4, the application of an RF signal as a primary signal at the primary winding 106 results in the formation of plasma current 130. In one embodiment, the frequency of the RF signal used may be 400 KHz, although those skilled in the art will appreciate that the RF signal frequency may range from about 4 KHz to 150 KHz or more. The plasma current 130 results in the formation of plasma 102 around the plasma source body 104. Throughout this document, although reference is made to a primary loop, primary winding, primary coil and primary winding coil, the same meaning is associated to each one of these terms and concerns a winding 106 that is energized by an external RF generator.

As shown in FIG. 5, the plasma source 100 includes an electrode 124 positioned proximate to the ferrite core 116. The approximate current path of the DBD ignition discharge 134 forms a path between the outer dielectric barrier surface 114 and a nearby grounded aluminum surface (not shown).

Advantageously, the plasma source 100 is small enough to integrate with other vacuum components, but still maintains high power density. Further, the plasma source 100 exhibits combined toroidal behaviors, both as inductively coupled plasma source and dielectric barrier discharge for ignition purposes.

Because ignition is more difficult when using an inductively coupled plasma (hereinafter ICP), a capacitive electrode may be included to assist in ignition. In this case, the dielectric alumina break 114 that completes the vacuum cavity (without forming a shorted turn) also serves as the barrier dielectric for a dielectric barrier discharge. The dielectric barrier discharge (DBD) can be operated in parallel or independently of the ICP source, that may be an ICP RF source. The DBD can be powered at the same frequency as the ICP, such as 400 kHz, or a higher or lower frequency. Operation of the capacitively coupled plasma (hereinafter CCP) at a higher frequency, such as 1 MHZ, will lead to improved capacitive coupling. The excitation voltage for the CCP can be applied as a continuous wave, or can be applied as a very short pulse, or a sequence of short pulses. After the ICP mode is achieved, the DBD electrode can be de activated. The dielectric barrier discharge is a subset of the CCP. A hybrid plasma source can also be constructed with a CCP, where both the positive and negative electrodes do not have a dielectric barrier.

Characteristic for the toroidal plasma source 100 is that at least one of its ignition electrode or starter electrode 124, ferrite core 114, thermal management structure 120, and potting cavity 118 are integrated on an atmospheric side of the vacuum cavity in a substantially toroidal shape. The purpose of having potting cavity 118 in such a plasma source 100 is to facilitate the effective heat transfer from the heat generating components to the thermal management structure 120, while simultaneously providing high voltage isolation between the primary winding 106 and the capacitive ignition electrode 124. Cooling of the ferrite core 116 is optimized by placing the thermal management structure 120 between the outside wall plasma source body member 112 and the ferrite core 116. At least one face of the ferrite core 116 is closely coupled with the thermal management structure 120. There is a significant heat load on the outside surface of the plasma source body member 112 from the plasma 102 (see FIG. 1). This heat load is dissipated in one side of the thermal management structure 120, while the ferrite core 116 is cooled by the other side of the thermal management structure 120. This arrangement results in more effective cooling and a lower operating temperature for the ferrite core 116. FIGS. 3-5 show one embodiment of the thermal management structure 120, but alternate embodiments can be constructed with additional thermal management structure 120. For example, two thermal management structures 120 can sandwich the ferrite core 116 such that the ferrite magnetic core 116 has very good thermal isolation from the plasma source body structure 112.

Those skilled in the art will appreciate that the embodiments shown in FIGS. 1-5 show only one embodiment of the toroidal plasma source 100 and various other configurations are within the scope of this document. For example, there are multiple options for the construction of the toroidal plasma source 100, such as with three sides metal and one side ceramic, two U channels made of metal with one centerline made of ceramic, and two U channels of ceramic, with a centerline of metal. Alternatively, the structure could be formed using two short ceramic tubes along the axis, where one forms the inner diameter and the other forms the outer diameter, and two flat metal end caps complete the structure. Optionally, the ignition electrodes are placed on the inside of the ceramic surfaces. In another embodiment, the plasma envelope structure is fabricated with substantially all plasma facing surfaces of the envelope made from a solid dielectric material, such as aluminum nitride or aluminum oxide. Dielectric surfaces facing the plasma discharge will have minimal parasitic capacitive coupling, which will reduce ion bombardment, erosion, and particle contamination. The interfaces between sections may be “o” ring sealed (with overlapping features to prevent direct plasma exposure), or bonded. The capacitive ignition electrode may be bonded, or silk screened and then co-fired on one or more dielectric members.

Placing capacitive ignition electrodes 124 on opposite faces of the minor diameter of the ferrite core 116 is advantageous since it facilitates the creation of a dielectric barrier discharge plasma that encompasses most of the minor diameter. Exemplarily the electrical parameters of the inductively coupled plasma are a loop voltage of around 4 V/cm, loop voltage of about 46 V, a core such as Epcos N87, a magnetic field of about 168 mT and core loss of about 2000 mW/cm³, resulting in 48 W of core dissipation, operating at a frequency of 400 KHz.

FIG. 6a illustrates the plasma source 100 comprising a dielectric U channel 602, a conductive ground 604, a capacitive electrode 606, the ferrite core 608, and the thermal management structure (e.g. cold plate) 610.

FIG. 6B illustrates the plasma source 100 surrounded by the capacitive discharge 612 and by the inductive toroidal discharge 614.

FIG. 7a illustrates the plasma source 100 comprising in addition to the dielectric U channel 602 and the capacitive electrode 606 and a ferrite core 608 additional elements, such as an O-ring 702.

FIG. 7b illustrates that the inductive toroidal discharge 614 occurs along an inductive discharge path 704 and that the plasma source includes as well a positive CCP electrode 708 and a negative CCP electrode 706.

The arrangements described in FIGS. 6a, 6b, 7a, and 7b generate a capacitively coupled plasma that overlaps almost entirely with the current path of the inductively coupled plasma. The capacitively coupled plasma will generate free electrons generally along the entire current path of the inductively coupled plasma. This will facilitate reliable ignition and transition to ICP operation over a wider range of operating conditions.

It is possible, with a relatively high-power density plasma in an open chamber, that not enough gas will enter the plasma, to fully utilize the plasma's power in dissociating gas into reactive radicals. In these operating conditions, a gas feed is required to direct input gas into the discharge region. When the plasma source is used for this application, the best place to inject the gas is in the central region of the source's toroid, since the power density is highest in this region. Alternatively, gas can be distributed along the top and bottom surfaces, or around the perimeter of the cavity to ensure that sufficient gas is entering the plasma. As it may be observed for example in FIGS. 8 and 9, via a plurality of gas inlets 802, gas is distributed in approximate planes along the top and bottom surfaces of the plasma source 100.

Alternative implementations are also envisioned for the plasma source. An alternative implementation, that is an inverted rod plasma source 1000, is shown in FIG. 10. As may be seen in FIG. 10, the inverted rod plasma source 1000 comprises at least: a dielectric tube 1002, a ferrite core 1004, a primary winding coil 1006, a water cooling tube 1008, a capacitive ignition electrode 1010, and an internal cavity for thermally conductive potting 1012. The plasma region 1014 forms in a vacuum space situated at the exterior of the dielectric tube 1002. In a conventional solenoid ICP, the vacuum space and the plasma (transformer secondary) is on the inside of a dielectric tube, and the primary is on the outside. In the alternative implementation, proposed by the present invention, the construction enables that the plasma 1014 forms loops on the outside of the dielectric tube 1002, and the primary winding coil 1006 is situated on the inside of the tube 1002. This enables the use of a ferrite core 1004, which improves the coupling efficiency of a transformer. Cooling water can be routed in a helical pattern around the ferrite core 1004 via the water cooling tube 1008, or it may be routed axially. The tube can be small in diameter (on the order of 0.75-1 inch). This allows the formation of a very small plasma loop diameter, and a correspondingly small plasma loop voltage of approximately 30V. Care must be taken to avoid forming a shorted turn of any conductor inside or outside of the dielectric tube 1002. Therefore, a structure at the ends of the dielectric tube 1002 that forms a vacuum seal must be made as well of dielectric. In this design approach the magnetic field extends beyond the ends of the dielectric tube 1002 and returns outside the diameter of the dielectric tube 1002. These fields may cause parasitic heating and power loss of nearby metal structures, such as chamber wall components that are too close.

Optionally, heat pipes may be utilized either in conjunction with the solenoid or toroidal implementation of the plasma source and may be configured to draw heat from the highest temperature regions of the plasma source to an outside surface of the source that is more easily dissipated. The outside surface can be cooled with natural convection to external air, forced convection, or a water-cooled plate. The hot side of the heat pipe can be potted in place with thermally conductive epoxy, ideally (for the rod implementation) between the dielectric tube 1002 and the ferrite core 1004. In this case, the heat pipes must be oriented such to avoid forming a shorted turn around the ferrite core 1004. The use of heat pipes 1102 is advantageous because they can move away from the source large amounts of heat in a very compact, passive physical format. A configuration of a rod plasma source 1000 with heat pipes is shown in FIG. 11.

Heat pipes are generally configured to have a fluid inside that is operating right at a boundary between vapor and liquid. The fluid is typically water, filled at a low pressure, such as a few Torr. As heat adds energy to the liquid at the hot end, it forms a vapor and pressure carries this vapor to the cold end. At the cold end, the vapor loses energy, condenses, which lowers the pressure. Capillary action then draws the liquid back to the hot end of the heat pipe and the cycle continues. Heat pipes are typically configured to maximize heat removal with a cold end temperature of approximately 20 degrees C. Exemplarily heat pipes, their constructional details and their disposition is illustrated in FIG. 11.

In some applications, it is desired to remove power from a plasma source when the plasma source is powered, but not to let the plasma source fall below a certain temperature when the plasma is off, and it is not generating power. For example, a plasma source can be placed in the pumping line to clean deposition from the pumping line. However, the pumping line and the plasma source may be kept at an elevated temperature such as 100° C. In this case, it is desired to remove power when the plasma source is on, but the temperature of the plasma source should not fall below 100° C. when the plasma source is off and not generating heat. If the temperature of the plasma source is too low, it can cause process gasses to condense and to create additional solid particle sources.

With this goal in mind, the heat pipe can be configured with a higher fill pressure such that the liquid to vapor transition occurs at a higher temperature. This configuration still allows high power to be moved only with a small temperature drop, but at a temperature that is below the vapor temperature, the heat pipe transfers little heat, so that the plasma source is not “overcooled”. An alternate solution is a heat pipe with a different media, such as sodium, lithium, or potassium, which has a different PT curve, to shift the heat removal to a higher temperature. The temperature threshold is exemplarily one of 100 C, 80 C, and 60 C.

The plasma sources 100 or 1000, discussed above, irrespective of their configuration, exhibit high power density, namely, moderate power in a small package, and electrodeless operation, but with a small plasma loop, and corresponding small plasma loop voltage. Further, they possess more robust ignition in a wider process window. The integrated DBD electrode enables more robust ignition in a wider process window, while enabling point of use radical generation for cleaning applications with minimal transport and recombination loss. Their construction is possible with all solid dielectric materials facing the plasma, and as such, resulting in minimal parasitic capacitive coupling, erosion, and corresponding reduced particles and contamination.

An application of the above-described plasma sources may be found in the placement of these in a small, compact environment, such as hard to clean regions of a semiconductor processing chamber shown in FIG. 12. This illustrative chamber consists of a gas box 1206, a showerhead 1208, an upper chamber region 1206, a wafer pedestal 1214, a wafer 1214, a pressure control valve 1216, and a pump 1218. A plasma source is placed upstream above the showerhead 1208. The placement of plasma source 100 or 1000 can be in the lower chamber 1202, above the pressure control valve 1216 and below the pedestal 1214. This integration of the inverted toroidal plasma source with a semiconductor processing chamber enables radicals to be generated in the bottom of the chamber while minimizing transport loss or recombination losses between the plasma and the surfaces in the bottom of the chamber to be cleaned. This can also be achieved with multiple plasma sources in a chamber, as illustrated in FIG. 13. Therein there are multiple plasma sources in a large multi-wafer chamber, for example a quad wafer chamber. Another possible arrangement, illustrated in FIG. 14, is to implement the toroidal plasma source 1408 in pipe 1406, as foreline cleaning, with unobstructed flow through the center of torus. The pipe cross section is enlarged to allow room in the vacuum space for the full plasma loop 1410. This implementation is useful for cleaning a vacuum pumping lining, or when placed above a deposition trap, for the purpose of cleaning the deposition from the trap to minimize tool downtime associated with trap maintenance and periodically removing byproduct from the trap.

FIG. 15 shows an alternate implementation, which is to enclose the plasma source in a compact vacuum enclosure. The enclosure may have a gas supply fitting 1502 to introduce gas to the plasma source 1508, and an outlet flange 1506. This configuration can be mounted closely coupled, but external, to a vacuum chamber or larger piping segment. Gas flowing through the enclosure passes through the plasma 1510. An isolation valve may be used in the gas delivery line, just upstream of the plasma source. This implementation allows a closely coupled remote plasma source, such that radicals can be delivered to the main vacuum chamber or vessel, with minimum recombination, but with minimum disruption to chamber volume, conductance, or flow patterns.

FIGS. 16a and 16b show a representative sidewall of a vacuum chamber 1602, with pockets 1606 formed in the sidewalls. Inverted plasma sources 1604 are positioned in these pockets. This implementation has the benefit of providing point of use plasma sources with line of sight between the plasma and chamber surfaces to be cleaned, while minimizing impact to the chamber volume, conductance, and flow patterns in the chamber.

The above-described plasma sources and their placement finds applicability in lower chamber cleaning, foreline cleaning, oxygen cleaning applications, and point of use cleaning.

Although the foregoing descriptions of certain preferred embodiments of the present invention have shown, described and pointed out some fundamental novel features of the invention, it will be understood that various omissions, substitutions, and changes in the form of the detail of the apparatus as illustrated as well as the uses thereof, may be made by those skilled in the art, without departing from the spirit of the invention. Consequently, the scope of the present invention should not be limited to the foregoing discussions and subsequent claims.

What is claimed:

1. A plasma source, comprising:
a plasma source body, comprising:
a plurality of magnetic cores;
a plurality of primary windings capable of being energized; and
a cooling structure;
wherein one or more sections of said plasma source body comprising a dielectric material, and
wherein, when said plurality of primary windings are energized, a plasma forms around an outer portion of said plasma source body.

2. The plasma source of claim 1, further comprising potting situated on said inner portion of said plasma source body.

3. The plasma source of claim 1, said plasma source body further comprising an electrode capable of forming a discharge for ignition.

4. The plasma source of claim 1, wherein said the plasma source body having a torus shape.

5. The plasma source of claim 1, wherein said the plasma source body having a cylindrical shape.

6. The plasma source of claim 1, wherein said cooling structure comprising water passages.

7. The plasma source of claim 6, wherein said water passages comprising a plurality of pipes capable of conducting heat after a temperature threshold of the plurality of pipes has been exceeded.

8. The plasma source of claim 4, wherein the plasma source comprising a torus shaped plasma source body having a diameter of less than 1 inch to approximately 4 inches, and a height of about 1.5 inches, and capable of operating at about 500-2000 W.

9. The plasma source of claim 8, the plasma source having a diameter of about 3.25 inches.

10. The plasma source of claim 1, wherein said plurality of magnetic cores are ferrite cores.

11. The plasma source of claim 2, wherein said plurality of magnetic cores being encased in a thermally conductive potting.

12. The plasma source of claim 1, wherein a ferrite core is coupled with a portion of the cooling structure, and the vessel is coupled with a second portion of the cooling structure.

13. The plasma source of claim 1, wherein input gas is injected into a plasma discharge region.

14. A plasma source, comprising:
a plasma source body formed from at least one plasma source body member and at least one dielectric break, the plasma source body defining at least one plasma source body passage therein;
at least one ferrite core positioned within the plasma source body passage;
at least one primary winding traversing at least a portion of the plasma source body, the primary winding positioned proximate to the ferrite core, the primary winding in communication with at least one source RF energy, wherein the application of RF energy to the primary winding results in the formation of a plasma proximate to an outer surface of the plasma source body; and
at least one thermal management structure positioned within the plasma source body passage proximate to the ferrite core, the thermal management structure in fluid communication with at least one fluid source via at least one thermal management system inlet on the plasma source body.

15. The plasma source of claim 14, said plasma source body further comprising at least one electrode positioned within the plasma source body, the electrode capable of forming a discharge for ignition of the plasma.

16. The plasma source of claim 14, wherein said the plasma source body has a torus shape.

17. The plasma source of claim 14, wherein said the plasma source body has a cylindrical shape.

18. The plasma source of claim 14, wherein the plasma source comprising a torus shaped plasma source body having a diameter of less than 1 inch to approximately 4 inches, and a height of about 1.5 inches, and capable of operating at about 500-2000 W.

19. The plasma source of claim 14, the at least one ferrite core is encased in a thermally conductive potting.
